(19) United States
(12) Patent Application Publication
(10) Pub. No.: US 2010/0014342 A1
(43) Pub. Date: Jan. 21, 2010

(54) SEMICONDUCTOR STORAGE DEVICE

(75) Inventors: Katsuhiko HOYA, Yokohama-shi (JP); Shinichiro SHIRATAKE, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/505,180

(22) Filed: Jul. 17, 2009

(30) Foreign Application Priority Data
Jul. 18, 2008 (JP) 2008-187358

(51) Int. Cl. G11C 11/22; G11C 11/24; G11C 8/00; G11C 5/14

(52) U.S. Cl. 365/145; 365/149; 365/230.03; 365/226

(57) ABSTRACT

A memory includes a cell block comprises memory cells connected in series; block select transistors connected to one ends of the cell blocks; bit lines; plate lines; a sense amplifier comprises an N-type sensor and a P-type sensor, the N-type sensor applying a low-level potential to the bit line, and the P-type sensor applying a high-level potential to the bit line; local data lines corresponding to the bit lines respectively and transmitting data; and a column select transistor between one of the bit lines and one of the local data lines; wherein either one of the P-type sensor and the N-type sensor is set in an inactive state with the other one of the P-type sensor and the N-type sensor being in an active state, when the column select transistor is turned on to transmit the data to be written from the local data line to the bit line.

### CROSS-REFERENCE TO RELATED APPLICATION

This application is based upon and claims the benefit of priority from the prior Japanese Patent Applications No. 2008-187358, filed on Jul. 18, 2008, the entire contents of which are incorporated herein by reference.

### BACKGROUND OF THE INVENTION

1. Field of the Invention

The present invention relates to a semiconductor storage device, and relates to, for example, a ferroelectric memory.

2. Related Art

A ferroelectric memory is a nonvolatile memory which uses the hysteresis of the polarization characteristics of a ferroelectric to store binary data according to the size of two polarizations of the ferroelectric. Differently from a DRAM, the ferroelectric memory retains data based on the degree of residual polarization. Accordingly, the ferroelectric memory generates a potential difference between the electrodes of a ferroelectric capacitor to read a signal charge through a bit line. The plate line connected to one electrode is driven to generate the potential difference between the electrodes of the ferroelectric capacitor. At this time, the data of a memory cell is destroyed. In other words, the ferroelectric capacitor is a destructive read type memory, in which a data read operation deteriorates data. Accordingly, after the data is read, the original data must be rewritten in the memory cell or a new write data must be written in the memory cell.

Generally, the write data received from the outside of a memory chip is transmitted from a local data line (DQ line) to a bit line. At this time, a column select transistor arranged between the local data line and the bit line must be turned on. It is desired to shorten a data transfer time for transmitting data from the local data line to the bit line to write the data in the ferroelectric memory at high speed. The column select transistor is controlled by a column select line CSL. Therefore, it is desired to shorten the pulse width of a column select signal transmitted through the column select line CSL in order to shorten the data transfer time. The size (W/L) of the column select transistor must be large to some extent to transmit a sufficient data to the bit line with a short pulse width.

However, when the size (W/L) of the column select transistor is made large, the noise transmitted to a sense amplifier is increased. Therefore, the size (W/L) of the column select transistor is limited. Accordingly, there is a problem that the data transfer time becomes long.

### SUMMARY OF THE INVENTION

A semiconductor storage device according to an embodiment of the present invention comprises: a plurality of cell blocks each of which comprises a plurality of memory cells connected in series, each of the memory cells comprising a ferroelectric capacitor and a cell transistor connected in parallel; word lines connected to gates of the cell transistors; block select transistors connected to one ends of the cell blocks; a plurality of bit lines connected to the one ends of the cell blocks through the block select transistors; plate lines connected to the other ends of the cell blocks; sense amplifiers each of which is connected between a first bit line and a second bit line of the bit lines and comprises an N-type sensor of N-type FETs and a P-type sensor of P-type FETs, data transmitted by the first bit line and data transmitted by the second bit line complement each other, the N-type sensor applying a low-level potential indicating a logic low to the first or the second bit line, and the P-type sensor applying a high-level potential indicating a logic high to the first or the second bit line; local data lines corresponding to the bit lines respectively and transmitting data to be read or data to be written; and column select transistors each of which intervenes between one of the bit lines and one of the local data lines;

wherein either one of the P-type sensor and the N-type sensor is set in an inactive state with the other one of the P-type sensor and the N-type sensor being in an active state, when the column select transistor is turned on to transmit the data to be written from the local data line to the bit line.

### BRIEF DESCRIPTION OF THE DRAWINGS

FIG. 1 is a circuit diagram showing an example of a ferroelectric memory according to a first embodiment of the present invention;

FIG. 2 is a timing diagram showing a data write operation of the ferroelectric memory according to the first embodiment;

FIG. 3 is a circuit diagram showing an example of a ferroelectric memory according to a second embodiment of the present invention;

FIG. 4A is a circuit diagram showing an internal structure of the offset voltage generator OSG;

FIG. 4B is a timing diagram showing an operation of the offset voltage generator OSG;

FIG. 5 is a timing diagram showing a data write operation of the ferroelectric memory according to the second embodiment;

FIG. 6 is a timing diagram showing a data write operation of a ferroelectric memory according to a third embodiment of the present invention;

FIG. 7 is a timing diagram showing a data write operation of a ferroelectric memory according to a fourth embodiment of the present invention;

FIG. 8 is a timing diagram showing a data write operation of a ferroelectric memory according to a fifth embodiment of the present invention;

FIG. 9 is a timing diagram showing a data write operation of a ferroelectric memory according to a sixth embodiment of the present invention;

FIG. 10 is a circuit diagram showing an example of a ferroelectric memory according to a seventh embodiment of the present invention;

FIG. 11 is a timing diagram showing a data write operation of the ferroelectric memory according to the seventh embodiment;

FIG. 12 a circuit diagram showing an example of a ferroelectric memory according to a eighth embodiment of the present invention;

FIG. 13 is a timing diagram showing a data write operation of the ferroelectric memory according to the eighth embodiment; and

FIG. 14 is a timing diagram showing a data write operation of a ferroelectric memory according to a ninth embodiment.

### DETAILED DESCRIPTION OF THE INVENTION

Hereinafter, the embodiments of the present invention will be explained referring to the drawings. These embodiments do not limit the present invention.

### First Embodiment

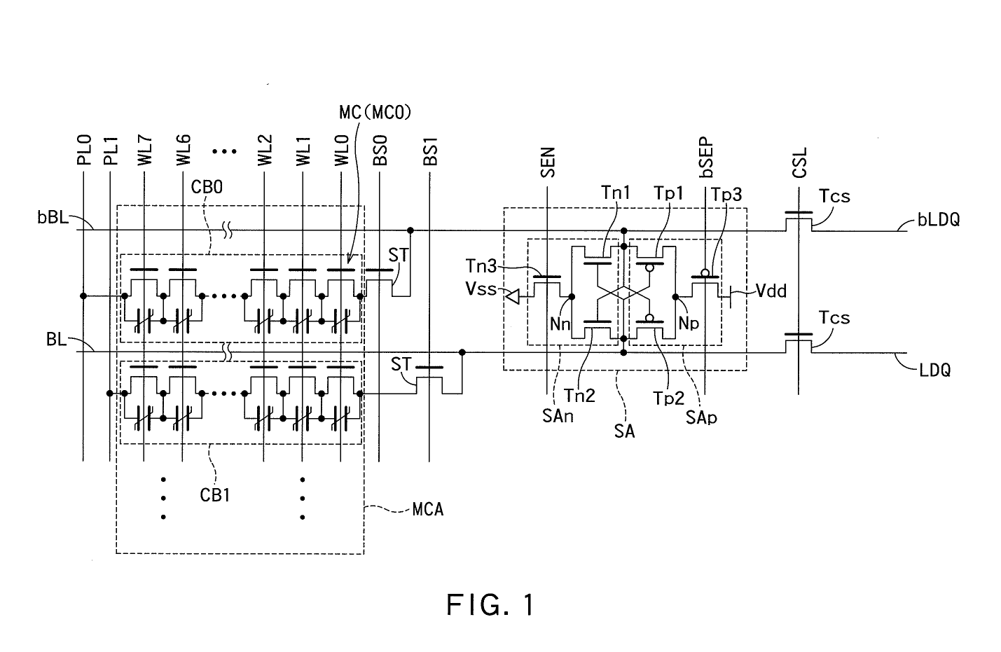

FIG. 1 is a circuit diagram showing an example of a ferroelectric memory according to a first embodiment of the present invention. The ferroelectric memory according to the first embodiment is a “Series connected TC unit type ferroelectric RAM,” which consists of series connected memory cells each having a transistor having a source terminal and a drain terminal and a ferroelectric capacitor inbetween said two terminals.

The first embodiment is not limited to the TC parallel unit series connection type ferroelectric memory and can be applied to any other kind of ferroelectric memory. The ferroelectric memory is a destructive read type memory. The destructive read type memory is a memory in which the data stored in a memory cell is deteriorated (destroyed) when the data is read from the memory cell. Therefore, when reading data from the memory cell of the destructive read type memory, write data from the outside must be written in the memory cell or the data detected by an sense amplifier SA must be rewritten (restored) in the memory cell.

The memory cell MC is a unit cell having one the cell transistor T and one ferroelectric capacitor C connected in parallel. A plurality of the memory cells MC are two-dimensionally arranged to form a memory cell array MCA. Each memory cell MC is arranged at each intersection of bit lines BL and word lines WL (each intersection of the bit lines BL and plate lines PL).

A plurality of the memory cells MC are connected in series to form one cell block CBi (i is an integer). In the first embodiment, one cell block CBi is formed of eight memory cells MC, for example. One end of the cell block CBi is connected to a bit line BL or a bit line bBL through a select transistor ST. The other end of the cell block CBi is connected to a plate line PLi. The gate of the cell transistor T is connected to a word line WLi. The select transistor ST is controlled by a block select signal BSi.

Although FIG. 1 shows only two cell blocks CBi, the memory cell array MCA may be formed of three or greater number of the cell blocks CBi. The number of the memory cells MC to form each cell block CBi is not limited to eight.

The data transmitted by the bit line BL and the data transmitted by the bit line bBL complement each other. For example, when the bit line bBL transmits information data of the cell block CB0, the bit line BL transmits reference data which is used to distinguish the logical value of the information data. The reference data is data showing an intermediate potential between the data “0” and the data “1.” A sense amplifier SA compares the information data and the reference data to detect the logical value of the information data.

The sense amplifier SA is connected between the bit line BL and the bit line bBL. The sense amplifier SA includes an N-type sensing circuit SAn formed of N-type MISFETs (Metal-Insulator Semiconductor Field-Effect Transistors) and a P-type sensing circuit SAp formed of P-type MISFETs.

The N-type sensing circuit SAn includes N-type transistors Tn1 and Tn2 connected in series between the bit line bBL and the bit line BL. The source or drain of the transistor Tn1 is connected to the bit line bBL, while the gate of the transistor Tn1 is connected to the bit line BL. The source or drain of the transistor Tn2 is connected to the bit line BL, while the gate of the transistor Tn2 is connected to the bit line bBL. Specifically, the gates of the transistor Tn1 and Tn2 are cross-coupled to the bit lines bBL and BL, respectively. A node Nn between the transistors Tn1 and Tn2 is connected to a low-level potential Vss through an N-type transistor Tn3. The transistor Tn3 is controlled by a sense amplifier activation signal SEN. The low-level potential Vss is, for example, a ground potential showing a logic low.

The P-type sensing circuit SAp includes P-type transistors Tp1 and Tp2 connected in series between the bit line bBL and the bit line BL. The source or drain of the transistor Tp1 is connected to the bit line bBL, while the gate of the transistor Tp1 is connected to the bit line BL. The source or drain of the transistor Tp2 is connected to the bit line BL, while the gate of the transistor Tp2 is connected to the bit line bBL. Specifically, the gates of the transistors Tp1 and Tp2 are cross-coupled to the bit lines bBL and BL, respectively. A node Np between the transistors Tp1 and Tp2 is connected to a high-level potential Vdd through a P-type transistor Tp3. The transistor Tp3 is controlled by a sense amplifier activation signal bSEP. The high-level potential Vdd is, for example, an internal power source potential showing a logic high. The sense amplifier SA has the function to latch the data of the bit lines bBL and BL.

Local data lines bLDQ and LDQ are arranged corresponding to the bit lines bBL and BL, respectively. Column select transistors Tcs are arranged between the local data line bLDQ and the bit line bBL and between the local data line LDQ and the bit line BL, respectively. Each column select transistor Tcs is an N-type MISFET. The local data lines bLDQ and LDQ are connected to a DQ buffer (not shown in the drawings) which temporarily stores read data or write data. The read data is read to the outside of a memory chip through the DQ buffer and an I/O circuit. The write data is transmitted to the sense amplifier SA through the I/O circuit and the DQ buffer. The write data latched in the sense amplifier SA is written in the selected memory cell MC through the bit lines bBL and BL.

The column of the data to be read or written is selected by the column select line CSL. The column select transistor Tcs of the selected column is turned on to transmit the data between the sense amplifier SA and the DQ buffer. The column select transistor Tcs of the unselected column is turned off. Accordingly, the original data detected by the sense amplifier SA is rewritten (restored) in the memory cells MC.

Here, the term activation or active state means turning on or driving an element or a circuit, while the term deactivation or inactive state means turning off or stopping the element or circuit. Therefore, it should be noted that the activation signal may be either of a logic high signal and a logic low signal. For example, an NMOS transistor is activated by setting its gate to be logic high. On the other hand, a PMOS transistor is activated by setting its gate to be logic low.

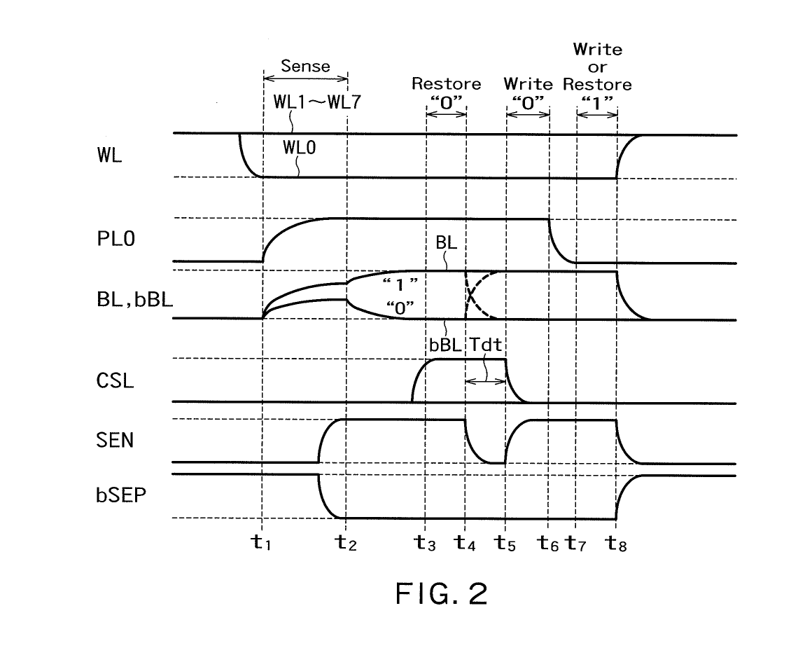

FIG. 2 is a timing diagram showing a data write operation of the ferroelectric memory according to the first embodiment. In an example shown in FIG. 2, the word line WL0 is the selected word line. Further, the data “0” is detected as the information data through the bit line bBL, while the data “1” is detected as the reference data through the bit line BL. Specifically, in this example, the memory cell MC0 shown in FIG. 1 is the selected memory cell. The data of the memory cell MC0 is detected to write data in the memory cell MC0. The data of the other memory cells, which are unselected, is detected to be changelessly restored. Since the operation when any other memory cell MC is the selected memory cell can be easily supposed, the explanation thereof will be omitted.

At t1, the word line WL0 is selected. The word line WL0 is deactivated, by which the cell transistor T of the memory cell MC0 is turned off. The word lines WL1 to WL7 maintain the active state. Accordingly, the potential difference between the bit line bBL and the plate line PL0 is applied only to the ferroelectric capacitor C of the memory cell MC0. The cell block CB1 is disconnected from the bit line BL by the select transistor ST connected to a block select line BS1.

At or immediately after t1, the potential of the plate line PL0 is raised. Accordingly, the information data stored in the ferroelectric capacitor C of the selected memory cell MC0 is transmitted to the bit line bBL. At this time, the reference data is transmitted to the bit line BL. The generating means of the reference data, although a detailed explanation thereof is not given, is similar to that of a well-known ferroelectric memory.

In the period from t1 to t2, the signal difference between the potentials of the data “0” stored in the selected memory cell MC0 and the reference data is developed between the bit lines bBL and BL. At t2, the sense amplifier activation signals SEN and bSEP are activated. By doing so, the sense amplifier SA amplifies and latches the signal difference between the bit lines bBL and BL.

At t3, a column is selected. The column select line CSL of the selected column is activated. The column select transistor Tcs is turned on and the bit lines bBL and BL are connected to the local data lines bLDQ and LDQ, respectively. At this time, the column select line CSL of the unselected column is in the inactive state. Therefore, the sense amplifier SA of the unselected column changelessly restores the detected data in the memory cell MC.

In the period from t3 to t4, since the plate line PL0 has the high-level potential, only the data “0” having the low-level potential is restored in the unselected memory cells MC. At this time, the data “1” is not restored. This is because the potential difference between the bit line having the high-level potential to transmit the data “1” and the plate line PL0 is not generated or very small.

At t4, the sense amplifier activation signal SEN is deactivated with the sense amplifier activation signal bSEP being in the active state. Accordingly, the P-type sensing circuit SAp maintains the active state while the N-type sensing circuit SAn is set in the inactive state. In the period from t4 to t5, the write data for the selected column is transmitted from the local data lines bLDQ and LDQ to the bit lines bBL and BL, respectively. When the information data stored in the memory cell MC has the logic reverse to that of the write data, the data states of the bit lines bBL and BL are reversed as shown by the broken lines in FIG. 2.

Obviously, when the information data stored in the memory cell MC has the same logical value as the write data, the data states of the bit lines bBL and BL are not reversed. However, in a conventional ferroelectric memory, there is a problem that the data transfer time becomes long when the data states of the bit lines bBL and BL are reversed. Accordingly, here, a case where the data states of the bit lines bBL and BL are reversed will be explained.

Generally, when the data states of the bit lines bBL and BL are reversed, the potentials of the local data lines bLDQ and LDQ are used to logically reverse the potentials of the bit lines bBL and BL. Here, the column select transistor Tcs is an N-type MISFET. It is difficult for the N-type MISFET to transmit the high-level potential. Therefore, in the data transfer time (t4 to t5) to transmit the write data for the selected column from the local data lines bLDQ and LDQ to the bit lines bBL and BL respectively, the time in which the data state (the data “0”) of the bit line bBL having the low-level potential is reversed to have the high-level potential (the data “1”) becomes long. Therefore, the data transfer time (t4 to t5) becomes long.

In order to solve the problem, in the first embodiment, the N-type sensing circuit SAn is set in the inactive state with the P-type sensing circuit SAp being in the active state. By setting the N-type sensing circuit SAn in the inactive state, the low-level potential Vss is disconnected from the bit line bBL. Accordingly, the potential of the bit line bBL of the selected column is easily increased. That is, the data state of the bit line bBL is reversed from the data “0” to the data “1” in a short time by setting the N-type sensing circuit SAn in the inactive state. Generally, it is easy for the N-type MISFET to transmit the low-level potential. In the first embodiment, the P-type sensing circuit SAp is kept in the active state. Since the P-type sensing circuit SAp is in the active state, the transistors Tp1 and Tp2 receive the low-level potential by the gates thereof and continue to apply the high-level potential Vdd to the bit line BL.

At t5, the column select line CSL is set in the inactive state and the sense amplifier activation signal SEN is activated again. Specifically, both of the P-type sensing circuit SAp and the N-type sensing circuit SAn are set in the active state. When the data “0” is to be written in the selected memory cell MC0, the data “0” is written in the selected memory cell MC0 in the period from t5 to t6. When the data “1” is to be written in the selected memory cell MC0, the data “1” is written in the memory cell MC0 not in the period from t5 to t6 but in the period from t7 to t8.

In the period from t6 to t7, the potential of the plate line PL0 is lowered. Accordingly, write operation of the data “0” is completed and write or restoration operation of the data “1” is started. In the period from t7 to t8, since the plate line PL0 has the low-level potential, the data “1” is written or restored in the memory cell MC. When the data “1” is to be written in the selected memory cell MC0, the data “1” is written in the selected memory cell MC0 in the period from t7 to t8. At this time, the data “1” is restored in the unselected memory cells in which the data “1” is stored. This is because the potential difference between the bit line and the plate line is reverse to that when writing the data “0” and is applied to the selected memory cell MC0 in which the data “1” is to be written and the unselected memory cells in which the data “1” is to be restored.

At t8, a series of write operations are completed. After t8, the ferroelectric memory is set in a precharge state.

According to the first embodiment, in a data transmission time Tdt, the N-type sensing circuit SAn is set in the inactive state with the P-type sensing circuit SAp being in the active state. Therefore, the low-level potential of the bit line can be raised to the high-level potential in a short time even when the column select transistor Tcs is an N-type MISFET. This means that the pulse width of the signal of the column select line CSL can be shortened. Accordingly, the time to restore and write data can be shortened and the entire operation of the ferroelectric memory can be performed at high speed.

### Second Embodiment

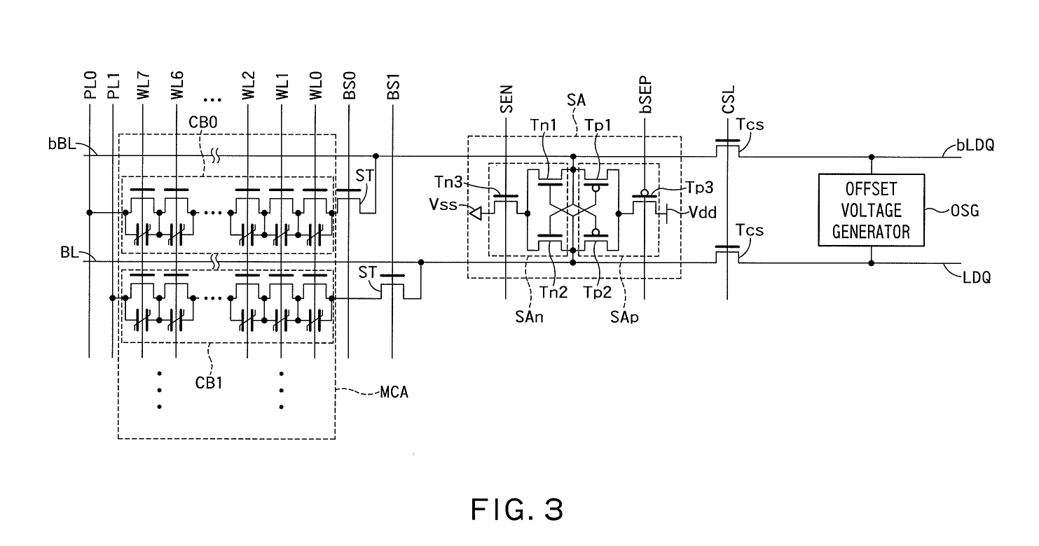

FIG. 3 is a circuit diagram showing an example of a ferroelectric memory according to a second embodiment of the present invention. The second embodiment is different from the first embodiment in that an offset voltage generator OSG is connected between the local data lines bLDQ and LDQ. The other components in the second embodiment are similar to those in the first embodiment. The offset voltage generator OSG may be connected between the bit lines bBL and BL.

As in the first embodiment, when the N-type sensor is set in the inactive state when transmitting data, the offset voltage generator OSG applies a potential which is equal to or smaller than the low-level potential Vss to the bit line bBL or BL.

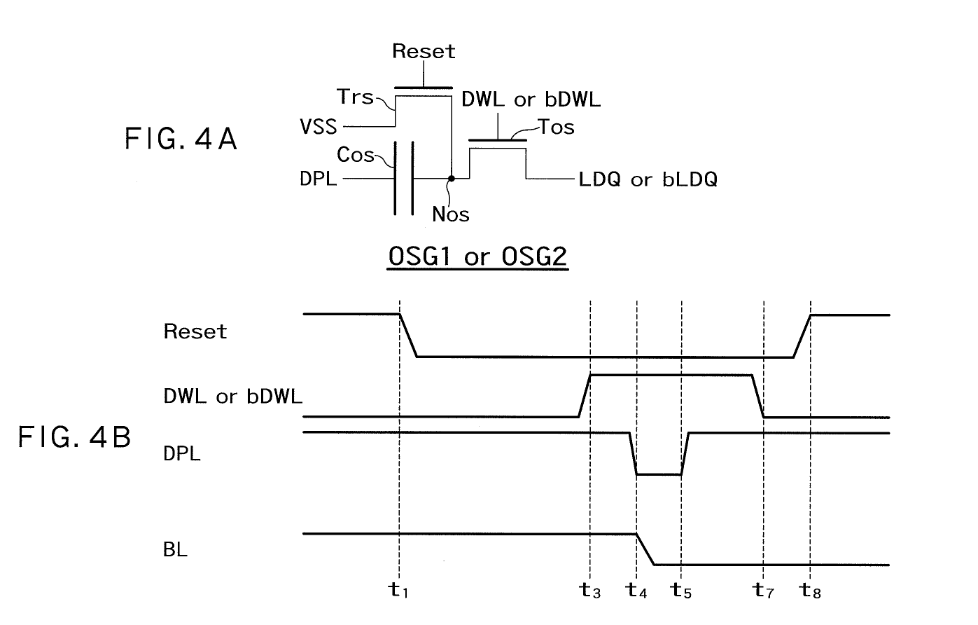

FIG. 4A is a circuit diagram showing an internal structure of the offset voltage generator OSG. The offset voltage generator OSG includes an offset capacitor Cos, a reset transistor Trs, and an offset transistor Tos. One ends of the offset capacitor Cos, the reset transistor Trs, and the offset transistor Tos are connected at a connection node Nos.

The other end of the offset capacitor Cos receives a pulse signal DPL. The other end of the reset transistor Trs is connected to the ground potential Vss and the gate thereof receives a signal Reset. The other end of the offset transistor Tos is connected to the local data line LDQ or bLDQ. The gate of the offset transistor Tos is connected to a signal DWL or a signal bDWL.

The offset voltage generator OSG has two components each of which is as shown in FIG. 4A: one is connected to the local data line LDQ, and the other is connected to the local data line bLDQ. Expediently, the voltage generator connected to the local data line LDQ is referred to as OSG1, while the voltage generator connected to the local data line bLDQ is referred to as OSG2. The voltage generators OSG1 and OSG2 receive the signals DWL and bDWL, respectively.

FIG. 4B is a timing diagram showing an operation of the offset voltage generator OSG. In a precharge state before t1, the node Nos is precharged with the ground potential Vss. At t1, the signal Reset is deactivated and the node Nos is disconnected from the ground potential Vss.

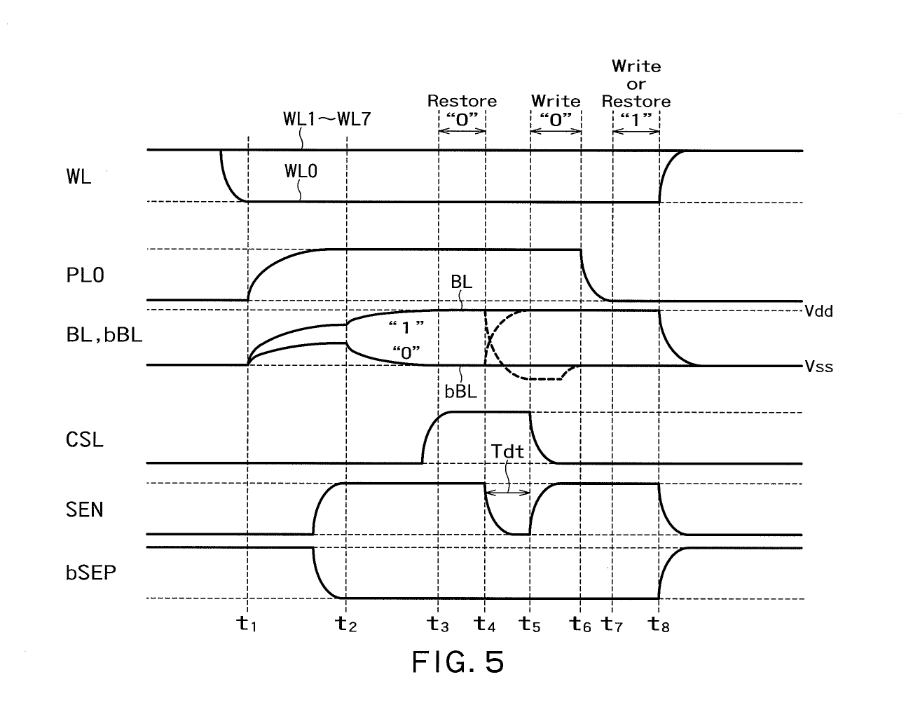

As shown in FIG. 5, the memory detects data to start a restoration operation at t3. At the same time, the signal DWL or bDWL is activated based on the data retained in the sense amplifier SA. Accordingly, the offset transistor Tos of the voltage generator OSG1 or OSG2 is turned on, and the potential of the local data line LDQ or bLDQ can be controlled by the signal DPL.

For example, as shown in FIG. 5, when the data “0” is to be written in the cell which has the data “1” and is connected to the bit line BL, the signal DWL is activated. In other words, the offset transistor Tos of the voltage generator OSG1, which is connected to the local data line LDQ corresponding to the bit line BL, is turned on.

At t4, which is immediately before the data “0” is written, the potential of the pulse signal DPL is lowered. The signal line of the pulse signal DPL is capacitive-coupled to the local data line LDQ through the offset capacitor Cos. Therefore, the potentials of the local data line LDQ and the bit line BL are suddenly decreased.

After that, at t5, the potential of the pulse signal DPL is raised, and at t7 or t8, the signal DWL or bDWL is set in the inactive state. Further, at t8, the signal Reset is set in the active state, by which the memory is set in a precharge state.

In the above concrete example, the cell having the data “1” is connected to the bit line BL. When the cell having the data “1” is connected to the bit line bBL, the voltage generator OSG2 is activated.

As stated above, the voltage generator OSG1 or OSG2 controls the potential of the local data line DQL or bDQL respectively, by which the low-level potential of the bit line can be decreased to be equal to or smaller than the ground potential Vss.

The voltage generators OSG1 and OSG2 shown in FIG. 4A may be connected to the bit lines BL and bBL, respectively.

FIG. 5 is a timing diagram showing a data write operation of the ferroelectric memory according to the second embodiment. The second embodiment is different from the first embodiment in the operation in the period from t4 to t6. The other operations in the second embodiment are similar to those in the first embodiment.

In the second embodiment, in the period from t4 to t6, the low-level potential of the bit line is decreased by the offset voltage generator OSG to be equal to or smaller than the ground potential Vss. Therefore, the potential difference applied to the memory cell MC in which the data “0” is to be written becomes large and the data “0” can be written in the memory cell MC in a short time.

In the second embodiment, in the data transfer time Tdt, the N-type sensing circuit SAn is set in the inactive state and the low-level potential of the bit line is decreased by the offset voltage generator OSG to be equal to or smaller than the ground potential Vss. Accordingly, the data transfer time Tdt can be further shortened and the time to write the data “0” in the selected memory cell MC0 can be shortened. Further, since the N-type sensing circuit SAn is in the inactive state, penetration current does not flow from the ground potential Vss to the offset voltage generator OSG when the low-level potential of the bit line is decreased to be equal to or smaller than the ground potential Vss. Since the penetration current does not flow, it is possible to restrict increase of a consumption current. This is because the ground potential Vss and the offset voltage generator OSG are disconnected from each other by the transistor Tn3.

### Third Embodiment

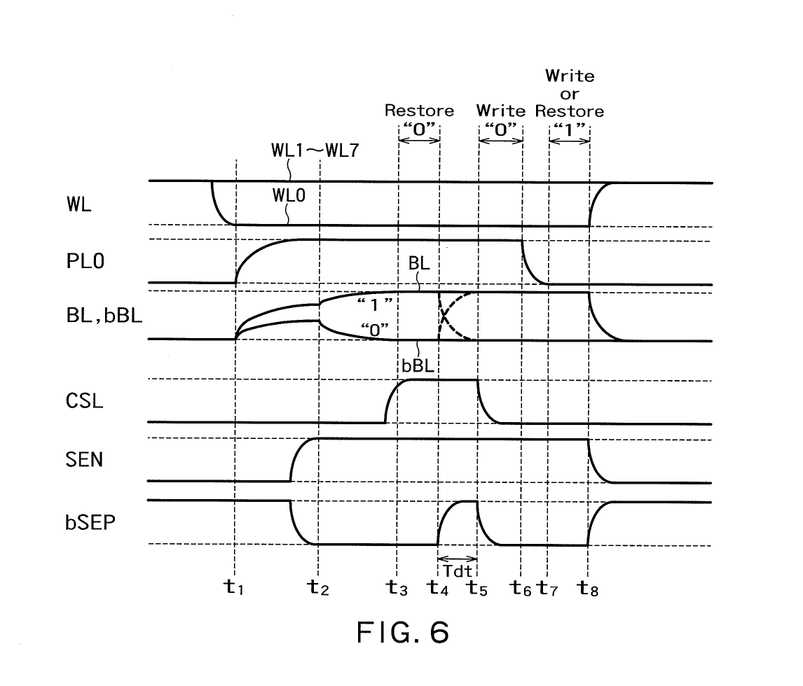

FIG. 6 is a timing diagram showing a data write operation of a ferroelectric memory according to a third embodiment of the present invention. The third embodiment is different from the first embodiment in that the sense amplifier activation signal bSEP is deactivated with the sense amplifier activation signal SEN being in the active state when transmitting data (t4 to t5). Therefore, the P-type sensing circuit SAp is set in the inactive state with the N-type sensing circuit SAn being in the active state when transmitting data (t4 to t5). The other operations in the third embodiment are similar to those in the first embodiment. At t5, the column select line CSL is set in the inactive state and the sense amplifier activation signal bSEP is activated again to have the low-level potential so that both of the P-type sensing circuit SAp and the N-type sensing circuit SAn are set in the active state.

The third embodiment is different from the first embodiment in that the column select transistor Tcs is a P-type MISFET. The other components in the third embodiment are similar to those in the first embodiment. Since the structural difference between the third embodiment and the first embodiment is small, the drawing showing the structure of the third embodiment will be omitted.

Generally, it is difficult for the P-type MISFET to transmit the low-level potential. Therefore, when the column select transistor Tcs is the P-type MISFET, it is desirable that the P-type sensing circuit SAp is set in the inactive state when transmitting data (t4 to t5). By setting the P-type sensing circuit SAp in the inactive state, the high-level potential Vdd is disconnected from the bit line BL. Accordingly, the high-level potential of the bit line BL of the selected column is easily decreased. That id, the data state of the bit line BL is reversed from the data “1” to the data “0” in a short time by setting the P-type sensing circuit SAp in the inactive state. Generally, it is easy for the P-type MISFET to transmit the high-level potential. Therefore, in the third embodiment, the N-type sensing circuit SAn is kept in the active state. Since the N-type sensing circuit SAn is in the active state, the transistors Tn1 and Tn2 receive the high-level potential by the gates thereof and continue to apply the low-level potential Vss to the bit line bBL.

As stated above, the time to restore and write data can be shortened even when the column select transistor Tcs is a P-type MISFET.

### Fourth Embodiment

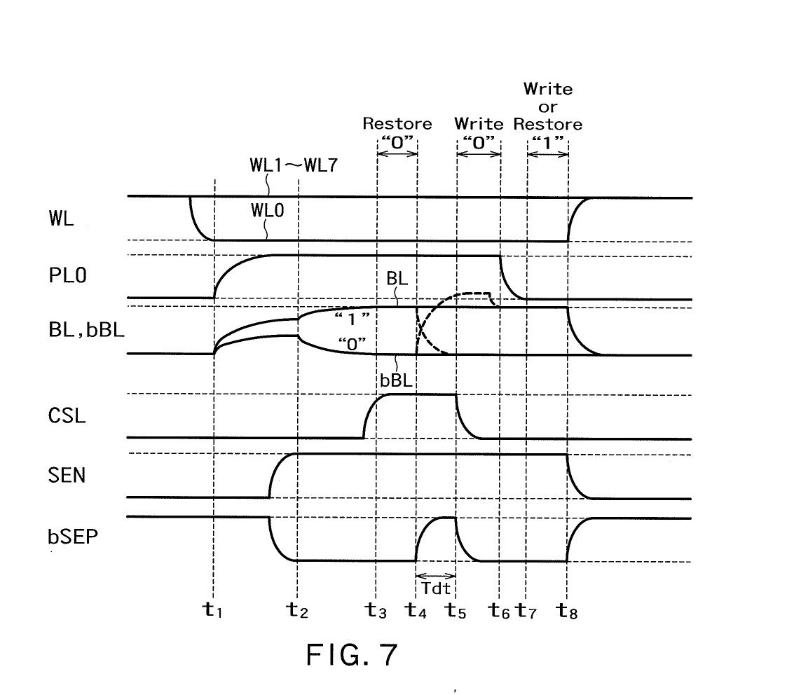

FIG. 7 is a timing diagram showing a data write operation of a ferroelectric memory according to a fourth embodiment of the present invention. The fourth embodiment is a combination of the second and third embodiments. Specifically, in the fourth embodiment, the column select transistor Tcs is a P-type MISFET and the offset voltage generator OSG is connected between the local data lines bLDQ and LDQ. The other components in the fourth embodiment are similar to those in the first embodiment. The offset voltage generator OSG may be connected between the bit lines bBL and BL.

In the fourth embodiment, as in the third embodiment, when the P-type sensor is set in the inactive state when transmitting data, the offset voltage generator OSG applies a potential, which is equal to or greater than the high-level potential Vdd, to the bit line bBL or BL.

The offset voltage generator OSG has the same structure as in the second embodiment. The voltage generators OSG1 and OSG2 shown in FIG. 4A may be connected to the bit lines BL and bBL, respectively.

The operation of the offset voltage generator OSG according to the fourth embodiment will be explained referring to FIG. 4B. As shown in FIG. 7, for example, when the data “1” is to be written in the cell which has the date “0” and is connected to the bit line bBL, the signal bDWL is activated by the offset voltage generator OSG. In other words, the offset transistor Tos of the voltage generator OSG2 connected to the local data line bLDQ is turned on.

The voltage level of the pulse signal DPL in the fourth embodiment is reverse to that shown in FIG. 4B. That is, before t4, the pulse signal DPL is low-level. At t4, which is immediately before the data “1” is written, the potential of the pulse signal DPL is raised, by which the potentials of the local data line bLDQ and the bit line bBL are suddenly increased. After t5, the potential of the pulse signal DPL is lowered to be low-level.

In the above concrete example, the cell having the “0” is connected to the bit line bBL. When the cell having the data “0” is connected to the bit line BL, the voltage generator OSG1 is activated.

Reference to FIG. 7 is made again. In the fourth embodiment, in the period from t4 to t6, the high-level potential of the bit line is increased by the offset voltage generator OSG to be equal to or greater than the high-level potential Vdd. Accordingly, the potential difference applied to the memory cell MC in which the data “1” is to be written becomes large and the data “1” can be written in a short time.

In the fourth embodiment, in the data transfer time Tdt, the P-type sensing circuit SAp is set in the inactive state and the potential of the bit line is increased by the offset voltage generator OSG to be equal to or greater than the high-level potential Vdd. As a result, the data transfer time Tdt is shortened and the time to write the data “1” is shortened. Further, since the P-type sensing circuit SAp is in the inactive state, penetration current does not flow from the offset voltage generator OSG to the power source Vdd when the potential of the bit line is increased to be equal to or greater than the high-level potential Vdd. Since the penetration current does not flow, it is possible to restrict increase of a consumption current. This is because the power source Vdd and the offset voltage generator OSG are disconnected from each other by the transistor Tp3.

### Fifth Embodiment

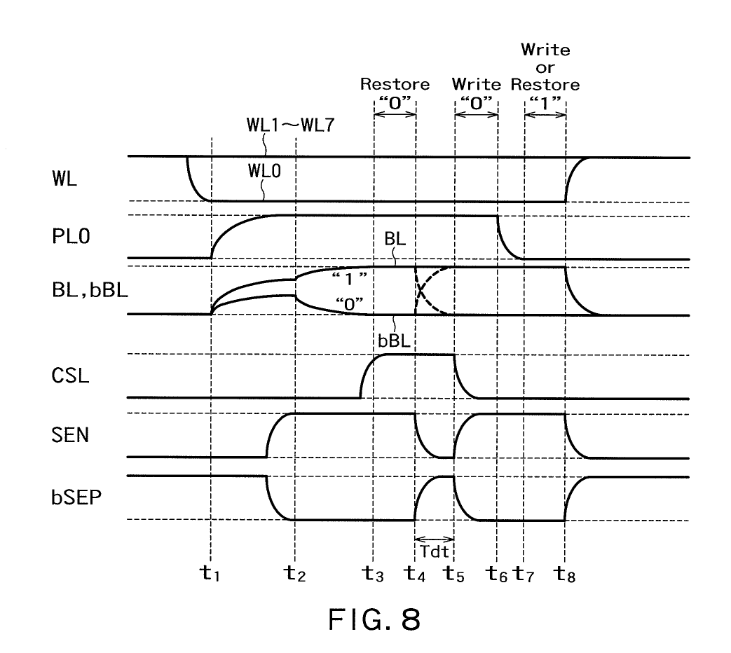

FIG. 8 is a timing diagram showing a data write operation of a ferroelectric memory according to a fifth embodiment of the present invention. The fifth embodiment is a combination of the first and third embodiments. Specifically, when transmitting data (t4 to t5), both of the sense amplifier activation signal SEN and the sense amplifier activation signal bSEP are deactivated. The other operations in the fifth embodiment are similar to those in the first embodiment. Further, the structure of the fifth embodiment is similar to that of the first embodiment. Note that the column select transistor Tcs may be either of an N-type MISFET and a P-type MISFET.

According to the fifth embodiment, since both of the N-type sensing circuit SAn and the P-type sensing circuit SAp are deactivated, the data transfer time Tdt is shortened. The effects as in the first and third embodiments also can be obtained in the fifth embodiment.

### Sixth Embodiment

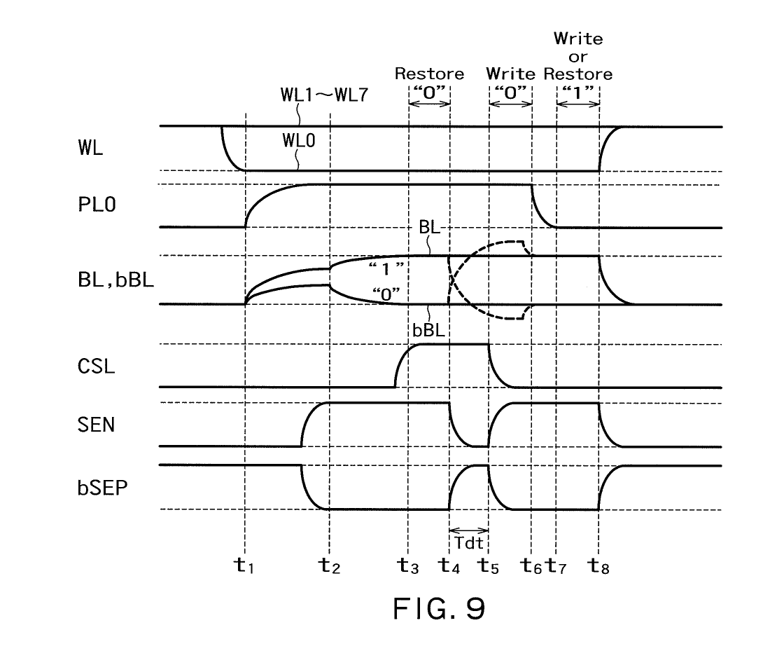

FIG. 9 is a timing diagram showing a data write operation of a ferroelectric memory according to a sixth embodiment of the present invention. The sixth embodiment is a combination of the second, fourth, and fifth embodiments. Specifically, the offset voltage generator OSG is connected between the local data lines bLDQ and LDQ, and when transmitting data (t4 to t5), both of the sense amplifier activation signal SEN and the sense amplifier activation signal bSEP are deactivated. The offset voltage generator OSG applies a potential which is equal to or smaller than the low-level potential Vss to one of the bit lines bBL and BL, and applies a potential which is equal to or greater than the high-level potential Vdd to the other one of the bit lines bBL and BL. In the sixth embodiment, the column select transistor Tcs may be either of an N-type MISFET and a P-type MISFET.

The offset voltage generator OSG has the same structure as in the second embodiment. The voltage generators OSG1 and OSG2 shown in FIG. 4A may be connected to the bit lines BL and bBL, respectively.

The operation of the offset voltage generator OSG according to the sixth embodiment will be explained referring to FIG. 4B. As shown in FIG. 9, for example, when the data “0” is to be written in the cell which is connected to the bit line BL and has the data “1” and when the data “1” is to be written in the cell which is connected to the bit line bBL and has the data “0,” both of the signals DWL and bDWL of the offset voltage generator OSG are activated. In other words, both of the offset transistors Tos of the voltage generators OSG1 and OSG2, which are connected to the local data lines LDQ and bLDQ respectively, are turned on.

In the sixth embodiment, the pulse signals DPL input to the voltage generators OSGL and OSG2 are reversed to each other. Specifically, the pulse signal DPL1 input to the voltage generator OSG1 operates similarly to the pulse signal DPL in the second embodiment. The signal DPL2 input to the voltage generator OSG2 operates similarly to the signal DPL in the fourth embodiment. Since the operations of the signals DPL1 and 2 can be easily supposed from FIG. 4B, the drawing thereof will be omitted.

Before t4, the pulse signal DPL1 is high-level, while the pulse signal DPL2 is low-level. At t4, the potential of the pulse signal DPL1 is lowered and the potential of DPL2 is raised. Accordingly, the potentials of the local data line LDQ and the bit line BL are suddenly decreased and the potentials of the local data line bLDQ and the bit line bBL are suddenly increased. After t5, the pulse signal DPL1 returns to be high-level, while the pulse signal DPL2 returns to be low-level.

In the above concrete example, the cell having the data “1” is connected to the bit line BL, while the cell having the data “0” is connected to the bit line bBL. When the cell having the data “0” is connected to the bit line BL and the cell having the data “1” is connected to the bit line bBL, the pulse signals DPL1 and DPL2 should be reversed to each other.

According to the sixth embodiment, since both of the N-type sensing circuit SAn and the P-type sensing circuit SAp are deactivated, the data transfer time Tdt is shortened.

According to the sixth embodiment, in the period from t4 to t6, the potential of the bit line is decreased by the offset voltage generator OSG to be equal to or smaller than the low-level potential Vss. As a result, the potential difference applied to the memory cell MC in which the data “0” is to be written becomes large and the data “0” can be written in a short time. Further, in the period from t4 to t6, the potential of the bit line is increased by the offset voltage generator OSG to be equal to or greater than the high-level potential Vdd. Therefore, the potential difference applied to the memory cell MC in which the data “1” is to be written becomes large and the data “1” can be written in a short time. Also in the sixth embodiment, the penetration current explained in the second and fourth embodiments is not generated.

### Seventh Embodiment

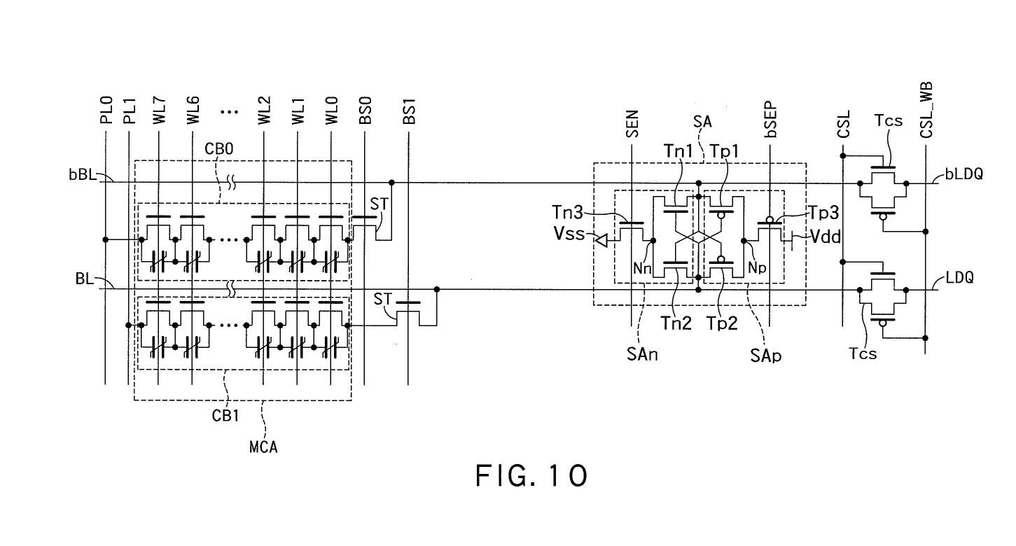

FIG. 10 is a circuit diagram showing an example of a ferroelectric memory according to a seventh embodiment of the present invention. The seventh embodiment is different from the first embodiment in that the column select transistor Tcs is formed of a P-type MISFET and an N-type MISFET connected in parallel. The other components in the seventh embodiment are similar to those in the first embodiment.

The N-type MISFET of the column select transistor Tcs is controlled by the signal of the column select line CSL, while the P-type MISFET is controlled by the signal of a column select line CSL_WB. When reading and writing data, the signal of the column select line CSL is activated in the period in which the data is transmitted between the bit line BL and the local data line LDQ and between the bit lines bBL and the local data lines bLDQ. When writing data, the signal of the column select line CSL_WB is activated in the data transfer time in which the data is transmitted from the local data lines LDQ and bLDQ to the bit lines BL and bBL, respectively. When reading data, the signal of the column select line CSL_WB is not activated. Therefore, the N-type MISFET of the column select transistor Tcs is turned on when reading and writing data, while the P-type MISFET of the column select transistor Tcs is turned on only when writing data.

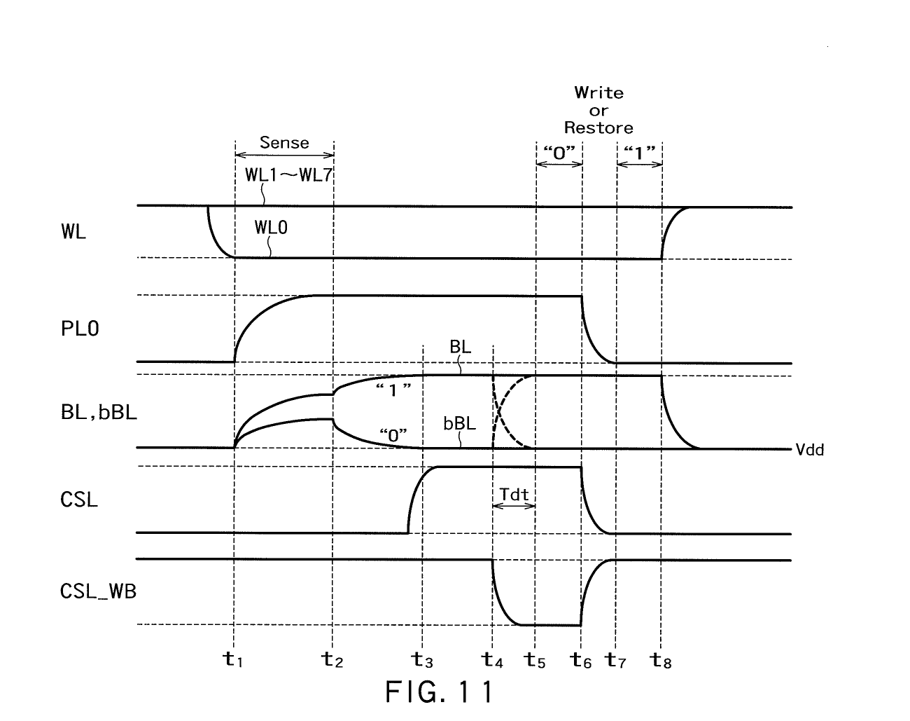

FIG. 11 is a timing diagram showing a data write operation of the ferroelectric memory according to the seventh embodiment. The signal operations of the column select lines CSL and CSL_WB in the seventh embodiment are different from that of the column select line CSL in the first embodiment. The other signal operations in the seventh embodiment are similar to those in the first embodiment.

In the period from t3 to t6, the signal of the column select line CSL is activated to have the high-level potential. In the period from t4 to t6, the signal of the column select line CSL_WB is activated to have the low-level potential. In the data transfer time Tdt (t4 to t5), the write data is transmitted from the local data lines LDQ and bLDQ to the bit lines BL and bBL, respectively. In the period from t5 to t6, the data “0” is written or restored in the memory cell MC. Therefore, the signal of the column select line CSL_WB is activated in the data transfer time Tdt and when writing (or restoring) the data “0.” Specifically, in the data transfer time Tdt and when writing (or restoring) the data “0,” the N-type MISFET and the P-type MISFET of the column select transistor Tcs are turned on. Accordingly, the write data having either of the high-level potential and the low-level potential can be transmitted at high speed from the local data lines LDQ and bLDQ to the bit lines BL and bBL, respectively. Further, a similar effect to the first embodiment can be obtained in the seventh embodiment.

The column select transistor Tcs in the seventh embodiment can be easily applied to the second to sixth embodiments. Therefore, the effect of any one of the second to sixth embodiments also can be additionally obtained in the seventh embodiment.

### Eighth Embodiment

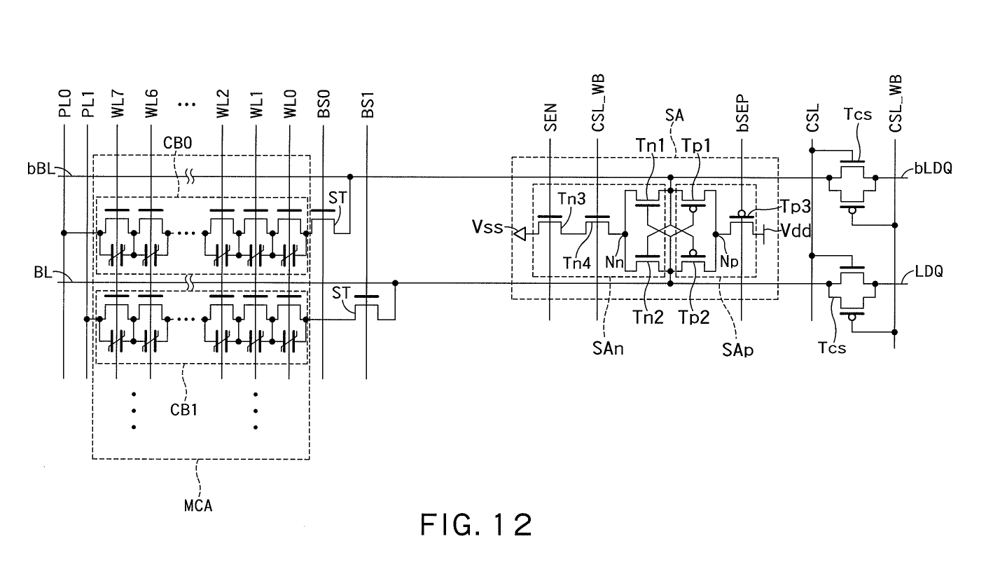

FIG. 12 a circuit diagram showing an example of a ferroelectric memory according to a eighth embodiment of the present invention. The eighth embodiment is different from the seventh embodiment in that an N-type transistor Tn4 is arranged between the node Nn and the transistor Tn3. The other components in the eighth embodiment are similar to those in the seventh embodiment. Similarly to the P-type MISFET of the column select transistor Tcs, the transistor Tn4 is controlled by the signal of the column select line CSL_WB. Accordingly, the transistor Tn4 and the P-type MISFET of the column select transistor Tcs are synchronously operated. However, the transistor Tn4, which is an N-type MISFET, operates reversely to the P-type MISFET of the column select transistor Tcs. That is, when the transistor Tn4 is turned on, the P-type MISFET of the column select transistor Tcs is turned off, while when the transistor Tn4 is turned off, the P-type MISFET of the column select transistor Tcs is turned on.

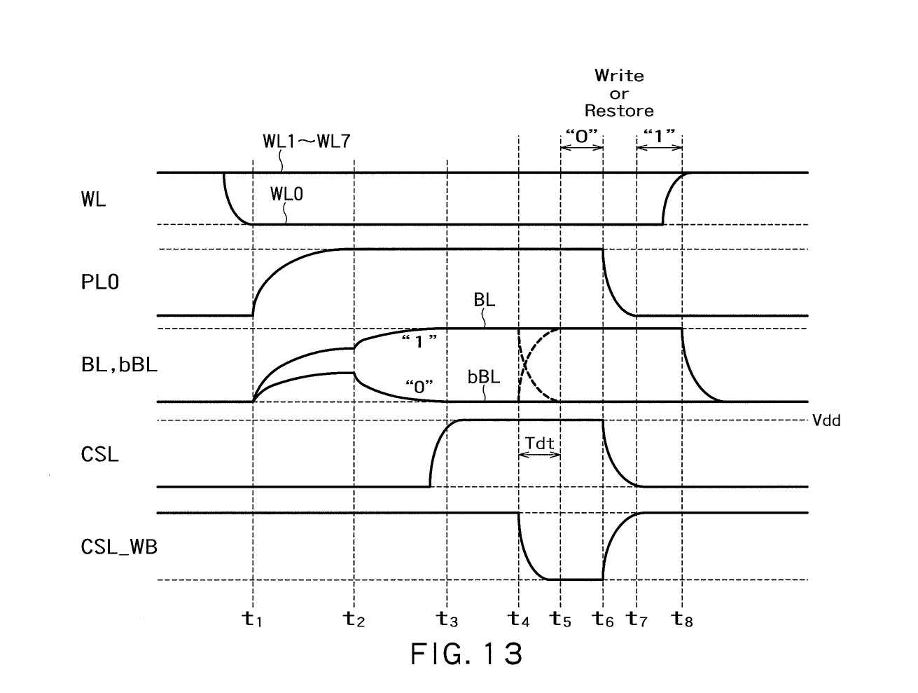

FIG. 13 is a timing diagram showing a data write operation of the ferroelectric memory according to the eighth embodiment. The operation in the eighth embodiment is basically similar to that in the seventh embodiment. However, in the data transfer time Tdt from t4 to t5, the sense amplifier activation signal SEN may maintain the active state (high-level potential). This is because, in the period from t4 to t6 including the data transfer time Tdt, the signal of the column select line CSL_WB has the low-level potential and the transistor Tn4 is turned off. Accordingly, in the period from t4 to t6, the N-type sensing circuit SAn is set in the inactive state. Reversely, the P-type MISFET of the column select transistor Tcs is turned on in the period from t4 to t6.

Accordingly, in the eighth embodiment, the write data having either of the high-level potential and the low-level potential can be transmitted at high speed from the local data lines LDQ and bLDQ to the bit lines BL and bBL, respectively. Further, a similar effect to the seventh embodiment can be obtained in the eighth embodiment.

The column select transistor Tcs and the N-type transistor Tn4 in the eighth embodiment can be easily applied to the second to sixth embodiments. Therefore, the effect of any one of the second to sixth embodiments can be additionally obtained in the eighth embodiment.

### Ninth Embodiment

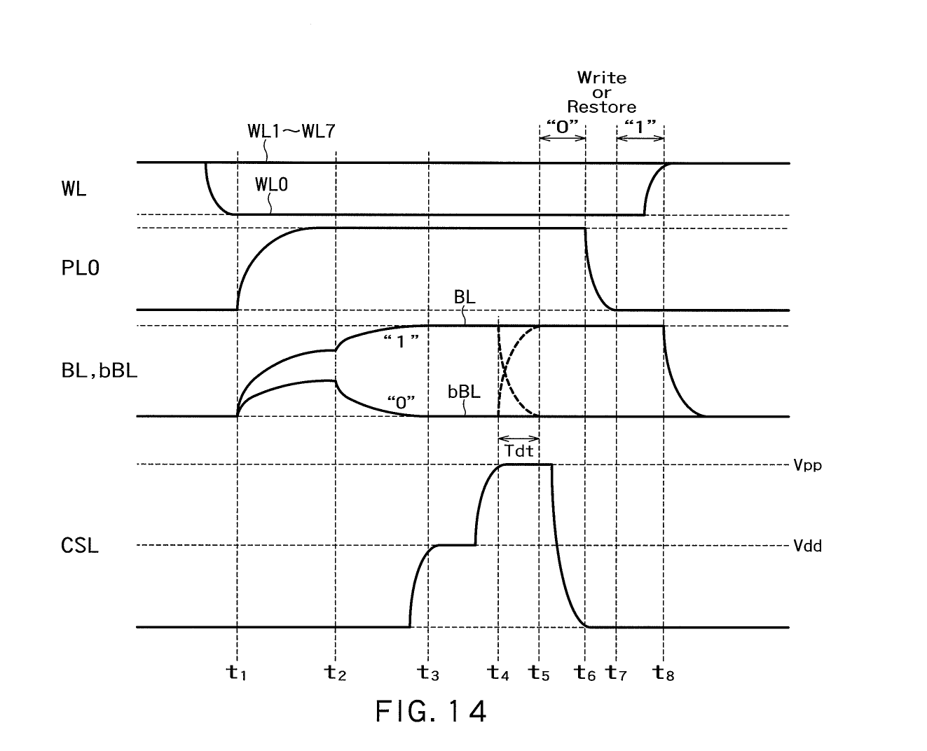

FIG. 14 is a timing diagram showing a data write operation of a ferroelectric memory according to a ninth embodiment. The structure of the ninth embodiment is similar to that of the first embodiment. In the ninth embodiment, the signal of the column select line CSL is controlled to have three values (Vss, Vdd, and Vpp). In the ninth embodiment, the operations performed in the period from t1 to t3 and in the period from t6 to t8 are similar to those in the first embodiment. In the data transfer time Tdt from t4 to t5, the signal potential of the column select line CSL is raised to be Vpp that is further higher than Vdd. As a result, the on-resistance of the column select transistor Tcs is reduced. Accordingly, in the ninth embodiment, data can be transmitted at high speed from the local data lines LDQ and bLDQ to the bit lines BL and bBL, respectively. Further, the effect of the first embodiment can be obtained in the ninth embodiment.

The signal operation of the column select line CSL in the eighth embodiment can be easily combined with any one of the second to seventh embodiments. As a result, the on-resistance of the column select transistor Tcs can be reduced and the data transfer time Tds can be further shortened.

1. A semiconductor storage device comprising:
a plurality of cell blocks, each comprising a plurality of memory cells connected in series, each memory cell comprising a ferroelectric capacitor and a cell transistor connected in parallel;
word lines connected to gates of the cell transistors;
block select transistors connected to first ends of the cell blocks;
a plurality of bit lines connected to the first ends of the cell blocks through the block select transistors;
plate lines connected to second ends of the cell blocks;
sense amplifiers, each connected between a first bit line and a second bit line of the bit lines and each comprises an N-type sensor of N-type Field-effect transistors (FETs) and a P-type sensor of P-type FETs, data transmitted by the first bit line and data transmitted by the second bit line complement each other, the N-type sensor applying a low-level potential indicating a logic low to the first or the second bit line, and the P-type sensor applying a high-level potential indicating a logic high to the first or the second bit line;
local data lines corresponding to the bit lines respectively configured to transmit data to be read or data to be written; and
column select transistors, each configured to intervene between one of the bit lines and one of the local data lines;
wherein either the P-type sensor or the N-type sensor is set in an inactive state with either the N-type sensor or the P-type sensor being in an active state, when the column select transistor is turned on in order to transmit the data to be written from the local data line to the bit line.

2. The device of claim 1, wherein
the N-type sensor is set in the inactive state with the P-type sensor being in the active state during transmitting the data from the local data line to the bit line, and
both of the P-type sensor and the N-type sensor are set in the active state, when the column select transistors are turned off in order to write the data transmitted to the bit lines in the memory cells.

3. The device of claim 1, wherein
the column select transistors are N-type FETs.

4. The device of claim 1, wherein
the P-type sensor is set in the inactive state with the N-type sensor being in the active state during transmitting the data from the local data line to the bit line, and
both of the P-type sensor and the N-type sensor are set in the active state, when the column select transistors are turned off to write the data transmitted to the bit lines in the memory cells.

5. The device of claim 4, wherein
the column select transistors are P-type FETs.

6. The device of claim 1, further comprising:
an offset voltage generator connected either between the first bit line and the second bit line or between the local data line corresponding to the first bit line and the local data line corresponding to the second bit line, wherein
the offset voltage generator is configured to apply a potential which is equal to or smaller than the low-level potential to either the first or the second bit line, if the N-type sensor is set in the inactive state during transmitting the data from the local data line to the bit line, or
the offset voltage generator is configured to apply a potential which is equal to or greater than the high-level potential to either the first or the second bit line, if the P-type sensor is set in an inactive state during transmitting the data from the local data line to the bit line.

7. The device of claim 2, further comprising:
an offset voltage generator connected either between the first bit line and the second bit line or between the local data line corresponding to the first bit line and the local data line corresponding to the second bit line, wherein
the offset voltage generator is configured to apply a potential which is equal to or smaller than the low-level potential to either the first or the second bit line, if the N-type sensor is set in the inactive state during transmitting the data from the local data line to the bit line, or
the offset voltage generator is configured to apply a potential which is equal to or greater than the high-level potential to either the first or the second bit line, if the P-type sensor is set in the inactive state during transmitting the data from the local data line to the bit line.

8. The device of claim 4, further comprising:
an offset voltage generator connected either between the first bit line and the second bit line or between the local data line corresponding to the first bit line and the local data line corresponding to the second bit line, wherein
the offset voltage generator is configured to apply a potential which is equal to or smaller than the low-level potential to either the first or the second bit line, if the N-type sensor is set in the inactive state during transmitting the data from the local data line to the bit line, or
the offset voltage generator is configured to apply a potential which is equal to or greater than the high-level potential to either the first or the second bit line, if the P-type sensor is set in the inactive state during transmitting the data from the local data line to the bit line.

9. The device of claim 1, wherein
the N-type sensor and the P-type sensor are set in the inactive state during transmitting the data from the local data line to the bit line, and
both of the P-type sensor and the N-type sensor are set in the active state, when the column select transistors are turned off in order to write the data transmitted to the bit lines in the memory cells.

10. The device of claim 1, further comprising:
an offset voltage generator connected either between the first bit line and the second bit line or between the local data line corresponding to the first bit line and the local data line corresponding to the second bit line, wherein
the N-type sensor and the P-type sensor are set in the inactive state during transmitting the data from the local data line to the bit line, and
the offset voltage generator is configured to apply a potential which is equal to or smaller than the low-level potential to either the first or the second bit line, and to apply a potential which is equal to or larger than the high-level potential the second or the first bit line, respectively.

11. The device of claim 1, wherein
each column select transistor comprises an N-type FET and a P-type FET connected in parallel to eath other, and
a combination of the N-type FET and the P-type FET of the column select transistors is set in an active state during transmitting the data from the local data line to the bit line.
